(19) United States
(12) Patent Application Publication
(10) Pub. No.: US 2023/0129950 A1
(43) Pub. Date: Apr. 27, 2023

(54) REVERSE-CONDUCTING INSULATED GATE BIPOLAR TRANSISTOR AND METHOD OF MANUFACTURING SAME

(71) Applicant: DB HiTek Co., Ltd., Bucheon-si (KR)

(72) Inventor: Hee Sung OH, Bucheon-si (KR)

(21) Appl. No.: 18/045,943

(22) Filed: Oct. 12, 2022

(30) Foreign Application Priority Data
Oct. 22, 2021 (KR) 10-2021-0141772

(51) Int. Cl. H01L 29/417; H01L 29/10; H01L 29/66; H01L 29/739

(52) U.S. Cl. CPC H01L 29/41708; H01L 29/1095; H01L 29/7397; H01L 29/66333

(57) ABSTRACT

A reverse-conducting insulated gate bipolar transistor and a method of manufacturing the same are disclosed. More particularly, the insulated gate bipolar transistor and the method of manufacturing the same are configured to form a cover layer so as to prevent external exposure of an uppermost surface of a first contact in a first cell region, thereby maximally reducing occurrences of contamination during subsequent processing.

### CROSS REFERENCE TO RELATED APPLICATION

The present application claims priority to Korean Patent Application No. 10-2021-0141772, filed Oct. 22, 2021, the entire contents of which are incorporated herein for all purposes by this reference.

### BACKGROUND OF THE INVENTION

### Field of the Invention

The present disclosure relates to a reverse-conducting insulated gate bipolar transistor and a method of manufacturing the same and, more particularly, to an insulated gate bipolar transistor and a method of manufacturing the same that are configured to form a cover layer so as to prevent external exposure of an uppermost surface of a first contact in a first cell region, thereby maximally reducing occurrences of contamination during subsequent processing.

### Description of the Related Art

Development of a reverse-conducting IGBT used as a power device for motor vehicles is in progress. The reverse-conducting IGBT includes a semiconductor substrate having an IGBT region including a general IGBT structure and a diode region including a diode structure. The diode structure is antiparallel to the IGBT structure, and typically operates as a freewheeling diode.

Hereinafter, the structure and problems of a conventional reverse-conducting insulated gate bipolar transistor will be described with reference to the accompanying drawings.

Referring to FIG. 1, in the conventional reverse-conducting insulated gate bipolar transistor 9, a first contact 920 is formed in an interlayer insulating film 910 on a substrate 901 in a first cell region C1, and a second contact 930 is formed in the interlayer insulating film 910 on the substrate 901 in a second cell region C2. By etching the interlayer insulating film 910, the first contact 920 and the second contact 930 may be formed simultaneously or substantially simultaneously. Describing in detail, the first contact 920 in the first cell region C1 and the second contact 930 in the second cell region C2 may be formed by etching the interlayer insulating film 910 on the substrate 901, and then forming an emitter electrode 940. Each of the etching process and the emitter electrode-forming process are respectively performed in the first cell region C1 and the second cell region C2 at the same time.

In this case, in order to improve a device switching speed, a body contact region (i.e., a high-concentration impurity doped region having a first conductivity type) should be adjacent to an emitter region 950 in the first cell region C1. The bottom of the body contact region may be lower than the bottom of the emitter region 950 and should be physically/electrically connected to the first contact 920. That is, in a process for forming a hole or opening for the first contact 920, a surface of the substrate 901 in the first cell region C1 should be etched by a predetermined depth, to a location of the body contact region.

A hole or opening for a second contact 930 in the second cell region C2 may be formed by etching the interlayer insulating film 910, but the first contact 920 in the first cell region C1 is formed by etching both the interlayer insulating film 910 and the surface of the substrate 901. Accordingly, since the holes or openings for the first contact 920 and the second contact 930 may have different depths, the first and second contacts 920 and 930 may not be formed through a conventional simultaneous process. As a result, there is a problem in that it is not easy to form the body contact region through the conventional process of simultaneously forming the first contact 920 and the second contact 930.

In addition, in the conventional structure 9 and manufacturing process thereof, a film 960 comprising Ti, titanium silicide and/or TiN is formed on the interlayer insulating film 910, on the open emitter region 950, and on the body region 955 in the second cell region C2. An emitter electrode 940 is formed on the layer 960. When the layer 960 comprising Ti or TiN is formed on the body region 955 (which comprises an impurity doped region having the first conductivity type), ohmic contact is not always possible, so there is also a problem that characteristics of the diode may deteriorate.

In order to solve these problems, the present inventor conceived a novel reverse-conducting insulated gate bipolar transistor having an improved structure and a method of manufacturing the same, which will be described in detail later.

### Documents of Related Art

Korean Patent Application Publication No. 10-2015-0046753 “RC-IGBT WITH FREEWHEELING SIC DIODE”

### SUMMARY OF THE INVENTION

The present disclosure has been devised to solve the problems of the related art, and an objective of the present disclosure is to provide a reverse-conducting insulated gate bipolar transistor and a method of manufacturing the same, wherein processes for forming a first contact in a first cell region and forming a second contact in a second cell region are separately performed, and the first contact has a relatively large upper and lower thicknesses so as to extend to a position in contact with a body contact region.

In addition, another obj ective of the present disclosure is to provide a reverse-conducting insulated gate bipolar transistor and a method of manufacturing the same, wherein an uppermost surface of a first contact is covered with a preliminary cover layer and/or a cover layer before forming a second contact region, so that a subsequent process such as forming a second contact is performed without exposing the uppermost surface of the first contact.

In addition, yet another objective of the present disclosure is to provide a reverse-conducting insulated gate bipolar transistor and a method of manufacturing the same, wherein the body region in the second cell region is covered with an insulating film or layer when a conductive film is formed in a first cell region, so that the conductive film does not contact the body region in the second cell region, thereby allowing an emitter electrode and the body region to come into ohmic contact.

The present disclosure may be implemented by exemplary embodiments having the following configurations in order to achieve the above-described objectives.

According to an exemplary embodiment of the present disclosure, a reverse-conducting insulated gate bipolar transistor according to the present disclosure includes a substrate; a collector electrode on the substrate; a collector layer on or in contact with the collector electrode in a first cell region; a cathode layer on or in contact with the collector electrode in a second cell region; a drift region on or over the collector layer and the cathode layer; a plurality of trench gates extending from a surface of the substrate (e.g., opposite from the collector electrode) in the first cell region and the second cell region, and spaced apart from each other (e.g., in a horizontal direction, or along the surface of the substrate); a body region on or over the drift region and between adjacent trench gates in the first cell region and the second cell region; an emitter region on or at the surface and on the body region in the first cell region; a body contact region adjacent to the emitter region and in the substrate; an interlayer insulating film on the substrate in the first cell region; and a first contact through the interlayer insulating film (e.g., in a vertical direction).

According to another exemplary embodiment of the present disclosure, the reverse-conducting insulated gate bipolar transistor according to the present disclosure may further include a barrier region on or below the body region and on the drift region in the first cell region and the second cell region.

According to yet another exemplary embodiment of the present disclosure, in the reverse-conducting insulated gate bipolar transistor according to the present disclosure, an uppermost surface of the body contact region may be lower than the surface of the substrate.

According to still another exemplary embodiment of the present disclosure, the reverse-conducting insulated gate bipolar transistor according to the present disclosure may further include a cover layer on the interlayer insulating film and the first contact in the first cell region.

According to still another exemplary embodiment of the present disclosure, the reverse-conducting insulated gate bipolar transistor according to the present disclosure may further include an emitter electrode on the interlayer insulating film, the first contact, and the surface of the substrate in the second cell region.

According to still another exemplary embodiment of the present disclosure, in the reverse-conducting insulated gate bipolar transistor according to the present disclosure, the cover layer may comprise a conductive metal.

According to still another exemplary embodiment of the present disclosure, in the reverse-conducting insulated gate bipolar transistor according to the present disclosure, the cover layer may comprise a nitride film, an oxide film, or a combination thereof.

According to still another exemplary embodiment of the present disclosure, a reverse-conducting insulated gate bipolar transistor according to the present disclosure includes a collector electrode on a substrate; a collector layer having a first conductivity type on or in contact with the collector electrode in a first cell region; a cathode layer having a second conductivity type on or in contact with the collector electrode in a second cell region; a drift region having the second conductivity type on or over the collector layer and the cathode layer; a plurality of trench gates extending from a surface of the substrate in the first cell region and second cell region, and spaced apart from each other (e.g., in a horizontal direction); a body region having the first conductivity type on or over the drift region and between adjacent trench gates in the first cell region and the second cell region; an emitter region having the second conductivity type on or at the surface of the substrate and on or over the body region in the first cell region; a body contact region having the first conductivity type in the body region (e.g., under the surface of the substrate); an interlayer insulating film (e.g., in which a second contact in the second cell region is to be formed), on the substrate in the first cell region; a first contact through the interlayer insulating film and at least partially into the substrate, connected to the body contact region and comprising a conductive metal; a cover layer comprising an inorganic film or a conductive metal film on the interlayer insulating film and the first contact; and an emitter electrode on the cover layer and the interlayer insulating film in the first cell region and on the substrate in the second cell region.

According to still another exemplary embodiment of the present disclosure, the reverse-conducting insulated gate bipolar transistor according to the present disclosure may further include a buffer layer having the second conductivity type on the collector layer and the cathode layer (e.g., in the first cell region and the second cell region, respectively).

According to still another exemplary embodiment of the present disclosure, in the reverse-conducting insulated gate bipolar transistor according to the present disclosure, the cover layer may at least partially cover an uppermost surface of the first contact.

According to still another exemplary embodiment of the present disclosure, the reverse-conducting insulated gate bipolar transistor according to the present disclosure may further include a conductive film on an outer surface of the first contact.

According to an exemplary embodiment of the present disclosure, a method of manufacturing a reverse-conducting insulated gate bipolar transistor according to the present disclosure includes forming trench gates extending from a substrate surface in a first cell region and a second cell region; forming a body region in a substrate and forming an emitter region on the body region in the first cell region, between adjacent trench gates; forming an insulating film or layer on the substrate surface in the first cell region and the second cell region; etching the insulating film or layer in the first cell region; forming a body contact region in the body region in the first cell region through the etched insulating film or layer; forming a first contact comprising a conductive metal in the etched insulating film or layer; and forming a preliminary cover layer on the insulating film or layer and the first contact.

According to another exemplary embodiment of the present disclosure, the method of manufacturing the reverse-conducting insulated gate bipolar transistor according to the present disclosure may further include etching the insulating film or layer and the preliminary cover layer so as to form a cover layer and expose the substrate surface in the second cell region; and forming an emitter electrode on the cover layer and the substrate surface in the second cell region.

According to yet another exemplary embodiment of the present disclosure, in the method of manufacturing the reverse-conducting insulated gate bipolar transistor according to the present disclosure, etching the insulating film or layer may include etching the insulating film or layer and the substrate thereunder by a predetermined depth; and the body contact region has an uppermost surface at a position lower than the substrate surface.

According to still another exemplary embodiment of the present disclosure, in the method of manufacturing the reverse-conducting insulated gate bipolar transistor according to the present disclosure, the preliminary cover layer may comprise an inorganic film, and partially covers an uppermost surface of the first contact.

According to still another exemplary embodiment of the present disclosure, a method of manufacturing a reverse-conducting insulated gate bipolar transistor according to the present disclosure includes forming trench gates extending from a substrate surface in a first cell region and a second cell region; forming a body region in a substrate and forming an emitter region on the body region in the first cell region, between adjacent trench gates; forming an interlayer insulating film on the substrate in the first cell region; forming a body contact region in the body region in the first cell region, spaced from the substrate surface; forming a first contact through the interlayer insulating film, connected to the body contact region and comprising a conductive metal material; forming a cover layer on the interlayer insulating film and the first contact; and forming an emitter electrode on the cover layer and on the substrate in the second cell region.

According to still another exemplary embodiment of the present disclosure, the method of manufacturing the reverse-conducting insulated gate bipolar transistor according to the present disclosure may further include forming a conductive layer on the interlayer insulating film (e.g., before forming the first contact).

According to still another exemplary embodiment of the present disclosure, in the method of manufacturing the reverse-conducting insulated gate bipolar transistor according to the present disclosure, the body region in the second region may be in direct contact with the emitter electrode.

According to still another exemplary embodiment of the present disclosure, the method of manufacturing the reverse-conducting insulated gate bipolar transistor according to the present disclosure may further include forming a barrier region in the first cell region and the second cell region. The barrier region may eventually be beneath the body region.

The present disclosure has the following effects by the above-described configuration.

The present disclosure provides processes for forming the first contact in the first cell region and forming the second contact in the second cell region separately, and the first contact has a relatively large thickness or height, and extends to and/or is in contact with the body contact region.

In addition, the present disclosure has an effect that the uppermost surface of the first contact is covered with the preliminary cover layer and/or the cover layer before forming the second contact, whereby subsequent processing, such as forming the second contact, is performed when the uppermost surface of the first contact is not exposed.

In addition, the present disclosure covers the body region in the second cell region with the insulating film or layer when the conductive film is formed in the first cell region, so that the conductive film does not contact the body region in the second cell region, thereby allowing the emitter electrode and the body region to come into ohmic contact.

Meanwhile, even though effects are not explicitly mentioned herein, it is affirmed that effects described in the following specification and potential effects thereof, the effects being expected by the technical features of the present disclosure, are treated as being described in the present disclosure.

### BRIEF DESCRIPTION OF THE DRAWINGS

FIG. 1 is a cross-sectional view illustrating a conventional reverse-conducting insulated gate bipolar transistor.

FIG. 2 is a cross-sectional view illustrating a reverse-conducting insulated gate bipolar transistor according to one or more exemplary embodiments of the present disclosure.

FIGS. 3 to 12 are cross-sectional views illustrating a method of manufacturing a reverse-conducting insulated gate bipolar transistor according to one or more exemplary embodiments of the present disclosure.

### DETAILED DESCRIPTION OF THE INVENTION

Hereinafter, exemplary embodiments of the present disclosure will be described in detail with reference to the accompanying drawings. The exemplary embodiments of the disclosure may be modified in various forms, and the scope of the present disclosure should not be construed as being limited to the following exemplary embodiments, but should be interpreted on the basis of the matters described in the claims. In addition, the present exemplary embodiments are only provided for reference in order to more completely describe the present disclosure to those skilled in the art.

In the following specification, a first component “on,” on “a top of,” on “an uppermost surface of” or on “an upper part of” a second component includes both the first component being in contact with the second element (or an upper surface thereof), as well as the first component being a certain distance apart from the second component. In addition, when the first component is spaced apart from the second component, another component may be between the two components. In addition, when the first component is “directly on the second component” or “directly above the second component,” no other component may be between the two components.

In addition, “first” and “second” configurations are described below, but it should be noted that a “second” configuration does not presuppose a “first” configuration, and is only for convenience of description.

Meanwhile, when one or more exemplary embodiments can be implemented differently, functions or operations specified in a specific block or sequence may occur differently from the order described (e.g., as may be depicted in a flowchart). For example, the functions or operations of two consecutive blocks or in a sequence may be performed substantially simultaneously or in reverse.

In the exemplary embodiment described below, as an example, a first conductivity type may be P-type, and a second conductivity type may be N-type, but the present disclosure is not necessarily limited thereto, and may be opposite or complementary to the above example.

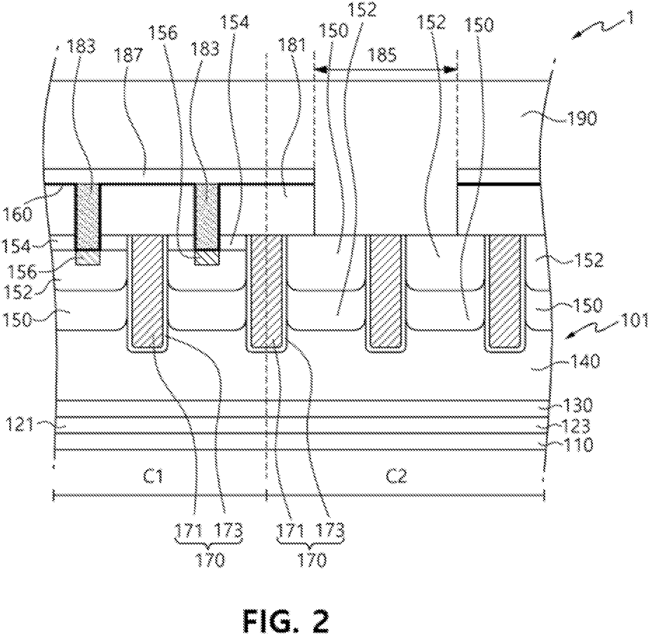

FIG. 2 is a cross-sectional view illustrating a reverse-conducting insulated gate bipolar transistor according to one or more exemplary embodiments of the present disclosure.

Hereinafter, the reverse-conducting insulated gate bipolar transistor (RC-IGBT) according to the exemplary embodiment(s) of the present disclosure will be described in detail with reference to the accompanying drawings.

Referring to FIG. 2, the present disclosure relates to a reverse-conducting insulated gate bipolar transistor 1 and, more particularly, to an insulated gate bipolar transistor that includes a cover layer 187 to prevent external exposure of an uppermost surface of a first contact 183 in a first cell region C1, thereby reducing occurrences of contamination during subsequent processing. Details will be described later.

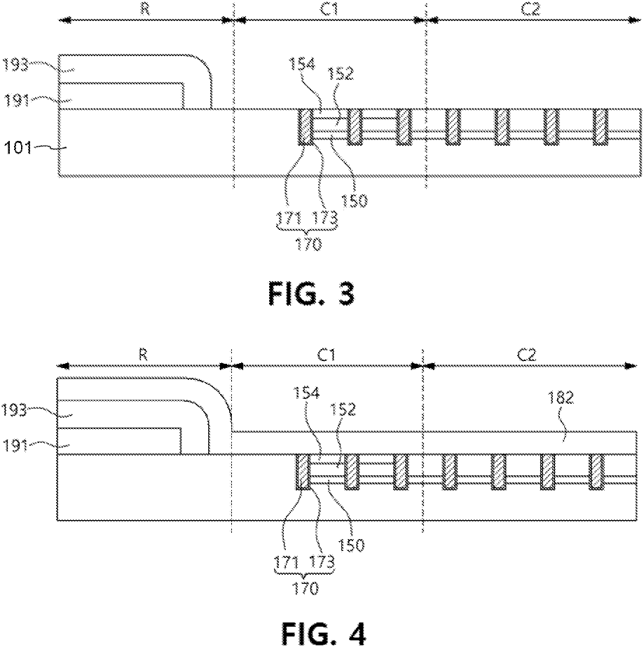

The reverse-conducting insulated gate bipolar transistor 1 may include a first cell region C1 serving as an IGBT region, a second cell region C2 serving as a diode region, and a ring region R (refer to FIG. 3) that is outside both the first cell area C1 and the second cell area C2. In addition, the reverse-conducting insulated gate bipolar transistor 1 may have a plurality of alternating first cell regions C1 and second cell regions C2 in at least some embodiments. The description of a schematic structure of the ring region R will be replaced by a description in a method of manufacturing the reverse-conducting insulated gate bipolar transistor to be described later. In addition, widths of the first cell region C1 and the second cell region C2 may differ from those shown in FIG. 2, and there is no special limitation thereto.

Hereinafter, a structure of the reverse-conducting insulated gate bipolar transistor 1 will be described in detail.

First, a collector electrode 110 is on a first surface of a substrate 101. Such a collector electrode 110 may comprise a conductive metal or alloy, for example, aluminum, nickel, gold, or an AlMoNiAu alloy, and may extend across the first cell region C1 and the second cell region C2. In addition, a collector layer 121 is on or under the collector electrode 110 in the first cell region C1. In addition, a cathode layer 123 is on or under the collector electrode 110 in the second cell region C2. The collector layer 121 may be or comprise a high-concentration impurity doped region having a first conductivity type, and the cathode layer 123 may be or comprise an impurity doped region having a second conductivity type. The collector layer 121 may partially traverse the second cell region C2 or be limited to the first cell region C1, but is not limited thereto.

In addition, a buffer layer 130 is on or under the collector layer 121 and the cathode layer 123. The buffer layer 130 may be or comprise a high-concentration impurity doped region having the second conductivity type. In addition, in the first cell region C1 and the second cell region C2, a drift region 140 may be on or under the collector layer 121 and the cathode layer 123, or on or under the buffer layer 130. The drift region 140 comprises an impurity doped region having the second conductivity type, and may be formed by, for example, epitaxial growth, but is not limited thereto.

In addition, a barrier region 150 may be on the drift region 140. The barrier region 150 comprises a high-concentration impurity doped region having the second conductivity type, and serves to increase a hole concentration and decrease a turn-on voltage in the drift region 140 through carrier accumulation. The barrier region 150 is in the first cell region C1 and the second cell region C2, and may be between adjacent trench gates 170.

Subsequently, a body region 152 that comprises an impurity doped region having the first conductivity type is on the barrier region 150 in the first cell region C1 and the second cell region C2, and a channel region (not shown) is in the body region 152. The channel region is inverted to the second conductivity type when the gate(s) are on to form a current path. The body region 152 may also be between adjacent trench gates 170.

In addition, in the first cell region C1, an emitter region 154, which comprises a high-concentration impurity doped region having the second conductivity type, is on the body region 152 and/or on a second surface of the substrate 101. The emitter region 154 is also between adjacent trench gates 170 in the first cell region C1, and may have, for example, a band shape. Accordingly, in the first cell region C1, the barrier region 150, the body region 152, and the emitter region 154 may be sequentially formed on a front side of the substrate 101. The emitter region 154 may physically contact or overlap a body contact region 156 to be described later.

The body contact region 156 comprises a high-concentration impurity doped region having the first conductivity type, and may partially overlap the emitter region 154 in the body region 152. Since the impurity concentration of the body contact region 156 is higher than that of the body region 152, and carriers may easily move through the body contact region 156, switching speed of the transistor 1 may be improved. In addition, the body contact region 156 is in the first cell region C1, but is not in the second cell region C2, and thus it is preferable that the bottommost surface of the body contact region 156 is lower than the bottommost surface of the adjacent emitter region 154. Alternatively, the body contact region 156 may be recessed a predetermined distance from the second surface of the adjacent substrate 101 (e.g., the uppermost surfaces of the body regions 152 in the second cell region C2 and the emitter regions 154 in the first cell region C1).

In addition, a plurality of trench gates 170 extending from the second surface of the substrate 101, and spaced apart from each other in a horizontal direction may be in the first cell region C1 and the second cell region C2. Each trench gate 170 may comprise a gate electrode 171 and a gate insulating layer 173 surrounding an outermost surface of the gate electrode 171. The gate electrode 171 may comprise a polysilicon film doped with a second conductivity type impurity, and the gate insulating layer 173 may comprise, for example, a silicon oxide film (e.g., doped or undoped silicon dioxide) and/or a nitride film (e.g., silicon nitride).

In addition, in the first cell region C1, an interlayer insulating layer 181 is on the trench gates 170 and the substrate 101. That is, an uppermost surface of each trench gate 170 is covered with the interlayer insulating layer 181. The interlayer insulating layer 181 may also comprise the same material(s) as that of the gate insulating layer 173 or a different material, but is not limited thereto. In addition, the interlayer insulating layer 181 may be on the substrate 101 (e.g., its second surface) in the second cell region C2.

In the first cell region C1, a first contact 183 traverses the interlayer insulating layer 181 in a vertical direction. The first contact 183 may pass through the interlayer insulating layer 181 in a vertical direction, but may connect to an individual body contact region 156. The first contact 183 may comprise a conductive metal material, for example, tungsten (W), but is not limited thereto. In addition, the first contact 183 may at least partially pass through the emitter region 154. In addition, a second contact 185 may pass through the interlayer insulating film 181 in the second cell region C2. The second contact 185 may electrically contact an emitter electrode 190 (to be described later). The second contact 185 may have a wide contact structure having a larger width or diameter than that of the first contact 183. In addition, in FIG. 2, the second contact 185 has a width sufficient to completely overlap an underlying trench gate 170, but is not limited thereto (refer, e.g., to FIG. 12).

In addition, a conductive layer 160 may be on a surface of the interlayer insulating layer 181 and on an outer surface of the first contact 183. For improved contact resistance and thermal stability, the conductive layer 160 may be formed by a self-aligned silicide process, using a metal such as titanium (Ti). However, the metal (e.g., Ti) deposited, but unsilicided, during the self-aligned silicide process is not removed in the first cell region C1.

In addition, a cover layer 187 is on or over the interlayer insulating film 181. The cover layer 187 at least partially covers an uppermost surface of the first contact 183, and comprises, for example, a conductive metal or alloy thereof, or an inorganic layer comprising an oxide film (e.g., silicon dioxide), a nitride film (e.g., silicon nitride), or a combination thereof. Describing a function of the cover layer 187, when an uppermost surface of the first contact 183 is exposed after formation of the first contact 183, there is a possibility that contamination may occur when a subsequent cleaning process is performed. Accordingly, the cleaning process may be performed after forming the cover layer 187 to block or cover the first contacts 183.

In addition, the cover layer 187 may completely cover the uppermost surface of the first contacts 183, or at least partially cover the uppermost surface of the first contacts 183, but is not limited thereto.

An emitter electrode 190 may be on the cover layer 187 and in openings in the interlayer insulating layer 181 in the second cell region C2. The emitter electrode 190 may comprise, for example, a polysilicon layer.

Hereinafter, together with the structure and problems of the conventional reverse-conducting insulated gate bipolar transistor 9, the structural features of the present disclosure for solving the problems will be described with reference to the accompanying drawings.

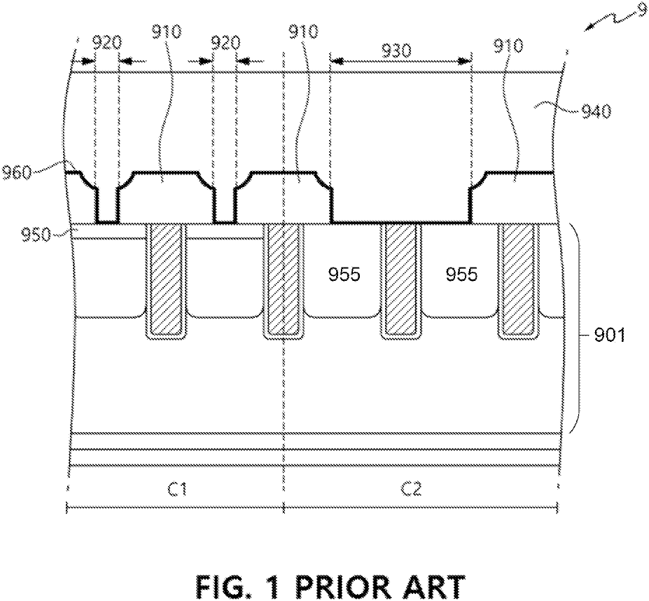

Referring to FIG. 1, in the conventional reverse-conducting insulated gate bipolar transistor 9, the first contact 920 is in the interlayer insulating film 910 on the substrate in the first cell region C1, and the second contact 930 is in the interlayer insulating film 910 on the substrate in the second cell region C2. Contact holes for the first contact 920 and the second contact 930 may be formed substantially simultaneously through the process of etching the interlayer insulating film 910. In addition, by etching the interlayer insulating film 910 and then forming the emitter electrode 940, the first contact 920 in the first cell region C1 and the second contact 930 in the second cell region C2 may be formed. As described above, an insulating film etching process and the emitter electrode-forming process are respectively performed in the first cell region C1 and the second cell region C2 at the same time.

In this case, in order to improve the device switching speed, the body contact region (i.e., a high-concentration impurity doped region having a first conductivity type) should be adjacent to the emitter region 950 in the first cell region C1. The bottom of the body contact region is lower than the bottom of the emitter region 950 and should be physically/electrically connected to the first contact 920. Accordingly, in a process for forming a hole or opening for the first contact 920, the surface of the substrate 901 on the side of the first cell region C1 should be etched by a predetermined depth, to a location of the body contact region.

The second contact 930 in the second cell region C2 may be formed by etching the interlayer insulating film 910, but the first contact 920 in the first cell region C1 is formed by etching both the interlayer insulating film 910 and the substrate 901. Accordingly, since the first contact 920 and the second contact 930 may have different depths, it is not easy for the body contact region to be formed in a correct position when the first contact 920 and the second contact 930 are formed through the conventional simultaneous process. As a result, there is a problem in that it is not easy to form the body contact region in the correct position using the conventional process of simultaneously forming the first contact 920 and the second contact 930.

In addition, in the conventional structure 9 or the process thereof, the film 960 made of Ti or TiN is formed on the interlayer insulating film 910, on the open emitter region 950, and on the body region in the second cell region C2. When the layer 960 is formed, an emitter electrode 940 is formed on the layer 960. In this case, when the layer 960 made of Ti or TiN is formed on the body region, which is an impurity doped region the first conductivity type, ohmic contact is not possible, so there is also a problem that diode characteristics are deteriorated.

In order to solve such problems, referring to FIG. 2, in the transistor 1 according to exemplary embodiment(s) of the present disclosure, the first contact 183 (and, optionally, the second contact 185) may comprise a material different from that of the emitter electrode 190, and may have different depths or heights from each other. The processes for forming the holes or openings for the first contact 183 and forming the second contact 185 are separately performed, and details thereof will be described later.

In addition, since the subsequent process of forming the second cell region C2 may be performed after the first contact 183 is covered with the cover layer 187, contamination may be reduced or prevented when performing subsequent processes such as a cleaning process. In addition, as described above, since the processes of forming the first cell region C1 and forming the second cell region C2 are separately performed, the conductive layer 160 may not be in or in part(s) of the second cell region C2, and a detailed description thereof will also be described later.

FIGS. 3 to 12 are cross-sectional views illustrating a method of manufacturing a reverse-conducting insulated gate bipolar transistor according to exemplary embodiments of the present disclosure.

Hereinafter, the method of manufacturing the reverse-conducting insulated gate bipolar transistor according to exemplary embodiments of the present disclosure will be described in detail with reference to the accompanying drawings.

First, referring to FIG. 3, in a first cell region C1 and a second cell region C2, trench gates 170 are conventionally formed to a predetermined depth from the surface of the substrate 101. The trench gates 170 may be spaced apart from each other in a horizontal direction. In addition, a barrier region 150 is conventionally formed (e.g., by ion implantation) between adjacent trench gates 170 at a predetermined depth in the substrate 101. A body region 152, which comprises an impurity doped region having the first conductivity type, is conventionally formed on, in or over the barrier region 150 (e.g., by ion implantation). An emitter region 154, which comprises an impurity doped region having the second conductivity type, is conventionally formed on or in the body region 152. The emitter region 154 is formed in the first cell region C1, but not in the second cell region C2, and may be formed by, for example, ion implantation. In addition, the barrier region 150 and the body region 152 may also be formed by ion implantation in both of the first cell region C1 and the second cell region C2.

In addition, a field oxide 191 constituting an oxide film (e.g., silicon dioxide) may be formed on the substrate 101 in the ring region R, and a gate electrode 193 may be conventionally formed on the field oxide 191.

Thereafter, referring to FIG. 4, an insulating film or layer 182 is deposited across the ring region R, the first cell region C1, and the second cell region C2. Describing in detail, the insulating film or layer 182 is formed on the gate electrode 191 and on the surface of the substrate 101 in the first cell region C1 and the second cell region C2. The insulating film or layer 182 may comprise an oxide layer (e.g., silicon dioxide), a nitride layer (e.g., silicon nitride), or a combination thereof, but is not limited thereto.

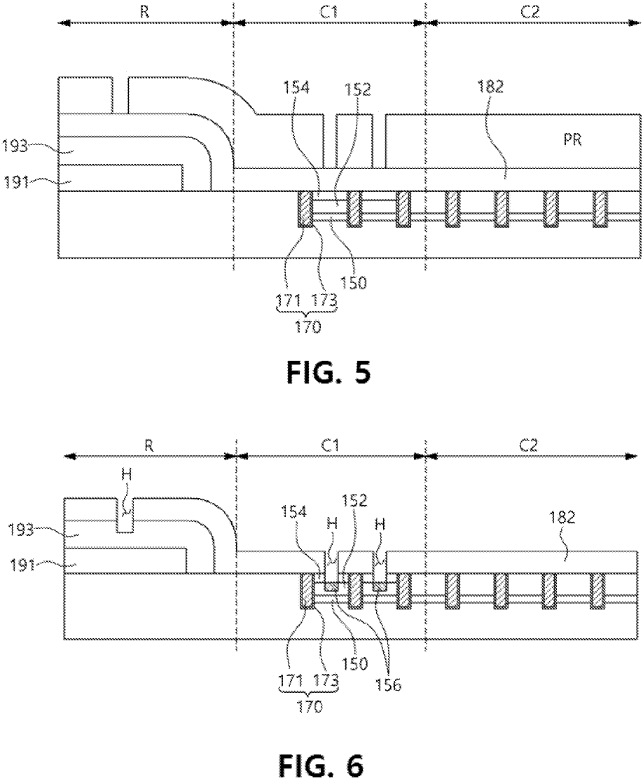

Then, referring to FIG. 5, a photoresist pattern PR is conventionally formed, and openings are conventionally formed in the insulating film or layer 182 in locations corresponding to a gate contact 189 (e.g., in the ring region R) and the first contact 183 (to be described later).

Thereafter, referring to FIG. 6, an etching process is performed using the photoresist pattern PR as a mask. Describing in detail, the insulating film or layer 182 and the gate electrode 193 are etched in the ring region R. In addition, the etching process is performed on the insulating film or layer 182 and the surface of the substrate 101 in the first cell region C1. The gate electrode 193 and the substrate 101 are partially etched in this process. The surface of the substrate 101 may be etched to a depth of, for example, about 4,000 Å. Accordingly, in the ring region R and the first cell region C1, contact holes H pass through the insulating film or layer 182. Thereafter, body contact regions 156 are formed in the substrate 101 through the contact holes H in the first cell region C1. The lowermost surface of the body contact region 156 may be lower than the lowermost surface of the adjacent or corresponding emitter region 154. The body contact regions 156 may be formed by ion implantation.

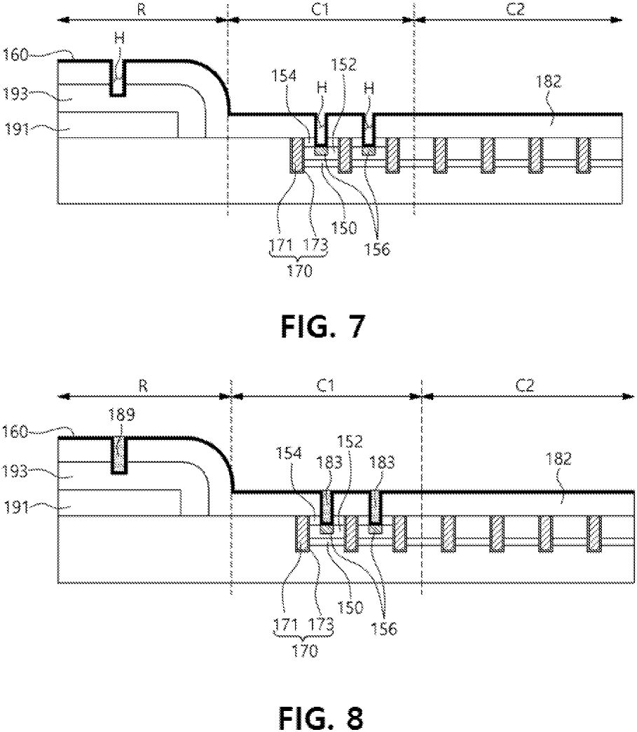

Thereafter, referring to FIG. 7, a conductive metal, metal nitride and/or metal silicide layer 160 is formed on an upper surface of the insulating film or layer 182 and in the contact holes H. The conductive layer 160 may be formed by conformally depositing, for example, a material comprising Ti, TiN, W, WN, Co, Ni, or a combination thereof, then annealing the material to form a metal silicide along the exposed surfaces of the gate electrode 193 and the substrate 101. As such, when the conductive layer 160 is formed, since the insulating film or layer 182 is already on the substrate 101 in the second cell region C2, the conductive layer 160 is not formed directly on the substrate 101 in the second cell region C2. Accordingly, when the second contact 185 is formed in a subsequent process, the body region 152 of the second cell region C2 and the conductive layer 160 are not in direct contact, so the emitter electrode 190 and the body region 152 may be in ohmic contact in the second cell region C2.

Referring to FIG. 8, after the conductive layer 160 is formed, the first contact 183 and the gate contact 189 are formed by filling the respective contact holes H with, for example, tungsten (W). According to one or more exemplary embodiments of the present disclosure, the first contact 183 is formed prior to the second contact 185 as described above. Conversely, if the second contact 185 is formed first, tungsten (W) would be deposited in the hole(s) in the insulating film or layer 182 for the second contact 185. Next, the contact hole H of the first cell region C1 would be filled with tungsten. Then, a sidewall may be formed on an inner wall of the insulating film or layer 182 defining the hole forming the second contact 185 during etching. In order to prevent this from occurring, the first contact 183 is formed first.

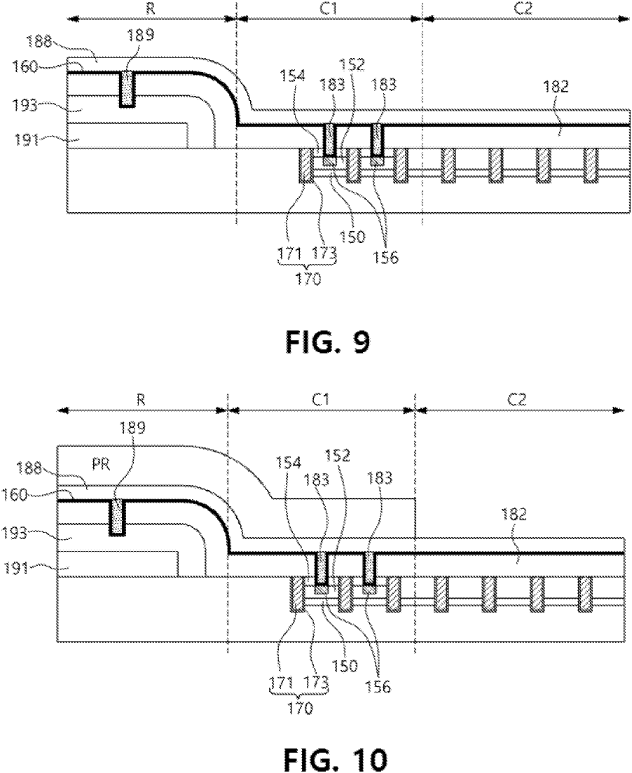

Referring to FIG. 9, after removing all of the tungsten (W) on the conductive layer 160, a preliminary cover layer 188, which comprises an insulating film or layer or a metal layer and which may form the cover layer 187 on the insulating film or layer 182, is formed across the ring region R, the first cell region C1, and the second cell region C2. The uppermost surfaces of the first contact 183 and the gate contact 189 may be at least partially covered by the preliminary cover layer 188.

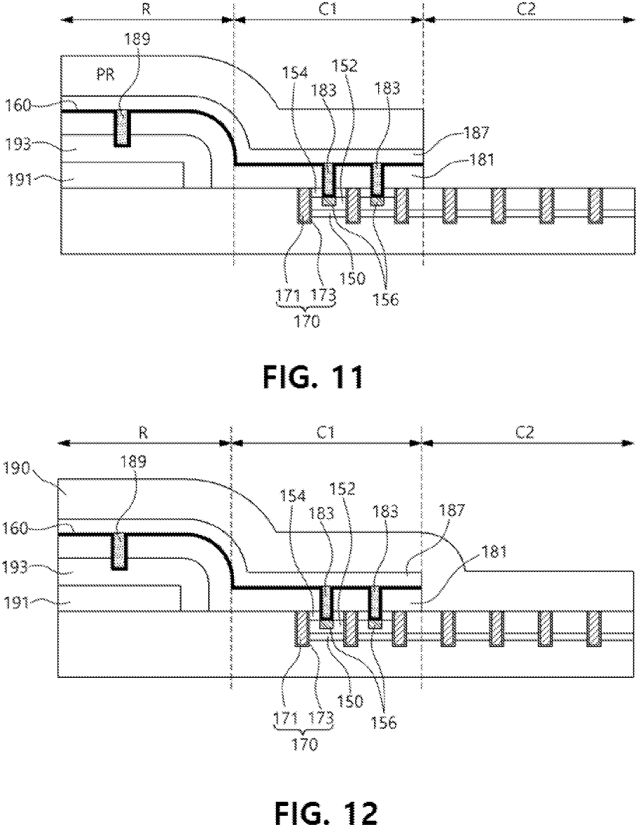

Then, referring to FIG. 10, a photoresist pattern PR is conventionally formed on the preliminary cover layer 188 except for the area(s) where the second contact 185 is to be formed. In one embodiment, the photoresist is removed from the entire or substantially the entire second cell region C2. In an alternative embodiment, the photoresist is removed in a manner exposing one or more trench gates 170 and two or more body regions 152 in the second cell region C2. In addition, referring to FIG. 11, the preliminary cover layer 188 and insulating film or layer 182 in the second cell region C2 are removed by etching using the photoresist pattern PR as a mask. As a result, a hole (i.e., a part open on the substrate of the second cell region C2) for the second contact 185 is formed in the second cell region C2, and the cover layer 187 and interlayer insulating film 181 in the first cell region C1 are completed.

After removing the photoresist pattern PR in the second cell region C2, referring to FIG. 12, an emitter electrode 190 is formed on the cover layer 187 in the ring region R and the first cell region C1, and on the surface of the substrate 101 in the second cell region C2. Accordingly, the second contact 185 is completed.

As described above, since the processes for forming the first contact 183 in the first cell region C1 and forming the second contact 185 in the second cell region C2 are separately performed, the first contact 183 may have a relatively large thickness or height, and thus may easily extend to a position in contact with the body contact region 156. In addition, prior to forming the second contact region 185, the first contact 183 is covered with the preliminary cover layer 188, and thus there is also an advantage that subsequent processing such as forming the second contact region 185 may be performed when the first contact 183 is not exposed.

In addition, when the conductive layer 160 in the first cell region C1 is formed, the body region(s) 152 in the second cell region C2 is/are covered with the insulating film or layer 182, so the conductive layer 160 may be prevented from contacting the body region(s) 152 in the second cell region C2.

The detailed description above is illustrative of the present disclosure. In addition, the above description shows and describes embodiments of the present disclosure, and the present disclosure may be used in various other combinations, modifications, and environments. That is, changes or modifications may be made within the scope of the concept of the disclosure in the present specification, the scope equivalent to the disclosed contents described previously, and/or the scope of the skill or knowledge of the art. The above-described exemplary embodiments are to describe the best state for implementing the technical idea of the present disclosure, and various modifications for specific applications or fields and uses of the present disclosure are possible. Therefore, the detailed description of the present disclosure is not intended to limit the present disclosure to the disclosed embodiments.

What is claimed is:

1. A reverse-conducting insulated gate bipolar transistor, the transistor comprising:
a substrate;
a collector electrode on the substrate;
a collector layer on or in contact with the collector electrode in a first cell region;
a cathode layer on in contact with the collector electrode in a second cell region;
a drift region on or over the collector layer and the cathode layer;
a plurality of trench gates extending from a surface of the substrate in the first cell region and the second cell region, and spaced apart from each other;
a body region on or over the drift region and between adjacent trench gates in the first cell region and the second cell region;
an emitter region on or at the surface of the substrate and on the body region in the first cell region;
a body contact region adjacent to the emitter region and in the substrate;
an interlayer insulating film on the substrate in the first cell region; and
a first contact through the interlayer insulating film.

2. The transistor of claim 1, further comprising:
a barrier region on or below the body region and on the drift region in the first cell region and the second cell region.

3. The transistor of claim 1, wherein an uppermost surface of the body contact region is lower than the surface of the substrate.

4. The transistor of claim 1, further comprising:
a cover layer on the interlayer insulating film and the first contact in the first cell region.

5. The transistor of claim 4, further comprising:
an emitter electrode on the interlayer insulating film, the first contact, and the surface of the substrate in the second cell region.

6. The transistor of claim 4, wherein the cover layer comprises a conductive metal.

7. The transistor of claim 4, wherein the cover layer comprises a nitride film, an oxide film, or a combination thereof.

8. A reverse-conducting insulated gate bipolar transistor, the transistor comprising:
a collector electrode on a substrate;
a collector layer having a first conductivity type on or in contact with the collector electrode in a first cell region;
a cathode layer having a second conductivity type on or in contact with the collector electrode in a second cell region;
a drift region having the second conductivity type on or over the collector layer and the cathode layer;
a plurality of trench gates extending from a substrate surface of the substrate in the first cell region and second cell region, and spaced apart from each other;
a body region having the first conductivity type on or over the drift region and between adjacent trench gates in the first cell region and the second cell region;
an emitter region having the second conductivity type on or at the surface of the substrate and on or over the body region in the first cell region;
a body contact region having the first conductivity type in the body region;
an interlayer insulating film on the substrate in the first cell region;
a first contact through the interlayer insulating film and at least partially into the substrate, connected to the body contact region and comprising a conductive metal;
a cover layer comprising an inorganic film or a conductive metal film on the interlayer insulating film and the first contact; and
an emitter electrode on the cover layer and the interlayer insulating film in the first cell region and on the substrate in the second cell region.

9. The transistor of claim 8, further comprising:
a buffer layer having the second conductivity type on the collector layer and the cathode layer.

10. The transistor of claim 8, wherein the cover layer at least partially covers an uppermost surface of the first contact.

11. The transistor of claim 8, further comprising:
a conductive film on an outer surface of the first contact.

12. A method of manufacturing a reverse-conducting insulated gate bipolar transistor, the method comprising:
forming trench gates extending from a substrate surface in a first cell region and a second cell region;
forming a body region in a substrate and forming an emitter region on the body region in the first cell region, between adjacent trench gates;
forming an insulating film or layer on the substrate surface in the first cell region and the second cell region;
etching the insulating film or layer in the first cell region;
forming a body contact region in the body region in the first cell region through the etched insulating film or layer;
forming a first contact comprising a conductive metal in the etched insulating film or layer; and
forming a preliminary cover layer on the insulating film or layer and the first contact.

13. The method of claim 12, further comprising:
etching the insulating film or layer and the preliminary cover layer so as to form a cover layer and expose the substrate surface in the second cell region; and
forming an emitter electrode on the cover layer and the substrate surface in the second cell region.

14. The method of claim 12, wherein etching the insulating film or layer comprises:
etching the insulating film or layer and the substrate thereunder by a predetermined depth; and the body contact region has an uppermost surface at a position lower than the substrate surface.

15. The method of claim 12, wherein the preliminary cover layer comprises an inorganic film, and partially covers an uppermost surface of the first contact.

16. A method of manufacturing a reverse-conducting insulated gate bipolar transistor, the method comprising:
forming trench gates configured to extend from a substrate surface in a first cell region and a second cell region;
forming a body region in a substrate and forming an emitter region on the body region in the first cell region, between adjacent trench gates;
forming an interlayer insulating film on the substrate in the first cell region;
forming a body contact region in the body region in the first cell region, spaced from the substrate surface;
forming a first contact through the interlayer insulating film, connected to the body contact region and comprising a conductive metal;
forming a cover layer on the interlayer insulating film and the first contact; and
forming an emitter electrode on the cover layer and on the substrate in the second cell region.

17. The method of claim 16, further comprising:
forming a conductive layer on the interlayer insulating film.

18. The method of claim 17, wherein the body region in the second region is in direct contact with the emitter electrode.

19. The method of claim 16, further comprising:
forming a barrier region in the first cell region and the second cell region.
